(19) United States
(12) Patent Application Publication
(10) Pub. No.: US 2026/0247978 A1
(43) Pub. Date: Aug. 20, 2026

(54) SEMICONDUCTOR DEVICE

(71) Applicant: Winbond Electronics Corp., Taichung City (TW)

(72) Inventors: Jin-Neng Wu, Kaohsiung City (TW); Shuo-Che Chang, Taichung (TW)

(73) Assignee: Winbond Electronics Corp., Taichung City (TW)

(21) Appl. No.: 19/466,519

(22) Filed: Feb. 2, 2026

(30) Foreign Application Priority Data
Feb. 14, 2025 (TW) 114105632

(51) Int. Cl. H10W 42/00; H10W 46/00

(52) U.S. Cl. CPC H10W 42/121; H10W 42/101; H10W 46/503

(57) ABSTRACT

A semiconductor device includes multiple semiconductor dies and a die-to-die interconnect. The semiconductor dies are located on both sides of a predetermined scribe-line area. The die-to-die interconnect electrically connects the semiconductor dies, in which in a top view, the die-to-die interconnect includes multiple crack-prevention corners located in the predetermined scribe-line area.

### CROSS-REFERENCE TO RELATED APPLICATION

This application claims the priority benefit of Taiwan application serial no. 114105632, filed on Feb. 14, 2025. The entirety of the above-mentioned patent application is hereby incorporated by reference herein and made a part of this specification.

### BACKGROUND

### Technical Field

The disclosure relates to a semiconductor device, particularly relates to a semiconductor device including a die-to-die interconnect with a crack-prevention structure.

### Related Art

Conventional integrated circuit fabrication methods mainly utilize masks to define the dimensions of each device component, where device performance is usually limited by two-dimensional chip dimensions. To improve the performance of integrated circuits (such as capacity or computing speed) within a limited area, the outcome may be achieved by reducing feature sizes and/or vertically stacking multiple chips. However, problems of reduced process yield and increased costs also arise. As the amount of information processing increases, the performance requirements for integrated circuits are also increasing. Typically, the respective chips in integrated circuits usually adopt a single die design. However, due to various factors such as process limitations and product yield, the single die design struggles to meet the increasingly demanding performance requirements.

To improve the performance of integrated circuits, during the wafer manufacturing stage, an inter-die metal line traversing scribe-line boundaries may be formed to make connections between circuits on the two dies, and the wafer may be appropriately diced to form a stitched chip including multiple electrically coupled dies. However, since the inter-die metal line is a straight line intersecting the dicing direction, cracks generated during the dicing process are prone to propagate along the inter-die metal line into the dies, which reduces the product yield.

### SUMMARY

The disclosure provides a semiconductor device that can improve the performance of integrated circuits and reduce damage caused during the dicing process.

An embodiment of the disclosure provides a semiconductor device, which includes multiple semiconductor dies and a die-to-die interconnect. The semiconductor dies are located on both sides of a predetermined scribe-line area. The die-to-die interconnect electrically connects the semiconductor dies, in which in a top view, the die-to-die interconnect includes multiple crack-prevention corners located in the predetermined scribe-line area.

Based on the above, the crack-prevention corners of the die-to-die interconnect according to the disclosure can prevent cracks generated during the dicing process from extending along the die-to-die interconnect into the semiconductor dies, thereby improving the product yield.

### BRIEF DESCRIPTION OF THE DRAWINGS

FIG. 1A is a top view schematic diagram of a semiconductor device according to an embodiment of the disclosure.

FIG. 1B is a partial enlarged view of FIG. 1A, showing a top view schematic diagram of die-to-die interconnects according to an embodiment of the disclosure.

FIG. 1C is a cross-sectional schematic diagram along a line A-A' in FIG. 1B.

FIG. 1D is a cross-sectional schematic diagram along a line B-B' in FIG. 1A.

FIG. 1E is a partial enlarged view of FIG. 1A, showing a top view schematic diagram of the die-to-die interconnects according to another embodiment of the disclosure.

FIG. 1F is a partial enlarged view of FIG. 1A, showing a top view schematic diagram of the die-to-die interconnects according to still another embodiment of the disclosure.

FIG. 1G is a partial enlarged view of FIG. 1D, showing a cross-sectional schematic diagram of a capacitor component according to an embodiment of the disclosure.

FIG. 2A is a top view schematic diagram of the semiconductor device according to an embodiment of the disclosure.

FIG. 2B is a partial enlarged view of FIG. 2A, showing a top view schematic diagram of cut die-to-die interconnects of the semiconductor device.

FIG. 2C is a cross-sectional schematic diagram along the line B-B' in FIG. 2A.

FIG. 3 is a partial top view schematic diagram of the semiconductor device according to an embodiment of the disclosure.

FIG. 4A is a top view schematic diagram of the die-to-die interconnects according to yet another embodiment of the disclosure.

FIG. 4B is a top view schematic diagram of the die-to-die interconnects in FIG. 4A after dicing.

FIG. 5A is a top view schematic diagram of the die-to-die interconnects according to a further embodiment of the disclosure.

FIG. 5B is a top view schematic diagram of the die-to-die interconnects in FIG. 5A after dicing.

FIG. 6A is a top view schematic diagram of a wafer according to an embodiment of the disclosure.

FIG. 6B is a partial enlarged view of FIG. 6A, showing a top view schematic diagram of die-to-die interconnects located between a first semiconductor die and a second semiconductor die in an intermediate step of the semiconductor device.

FIG. 6C is a cross-sectional schematic diagram along the line B-B' in FIG. 6A.

FIG. 7A is a top view schematic diagram of the semiconductor device according to an embodiment of the disclosure.

FIG. 7B is a partial cross-sectional schematic diagram of the semiconductor device in FIG. 7A.

### DESCRIPTION OF THE EMBODIMENTS

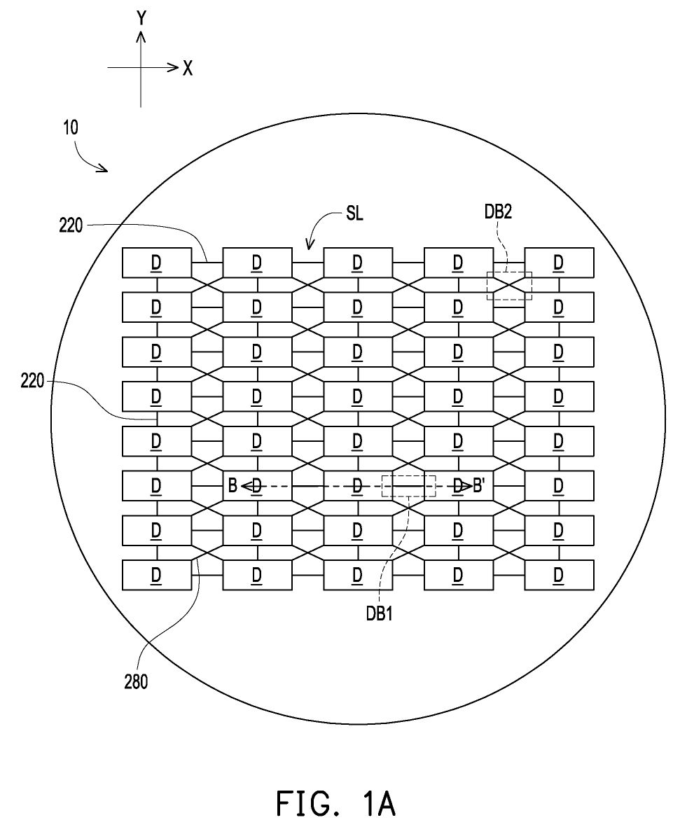

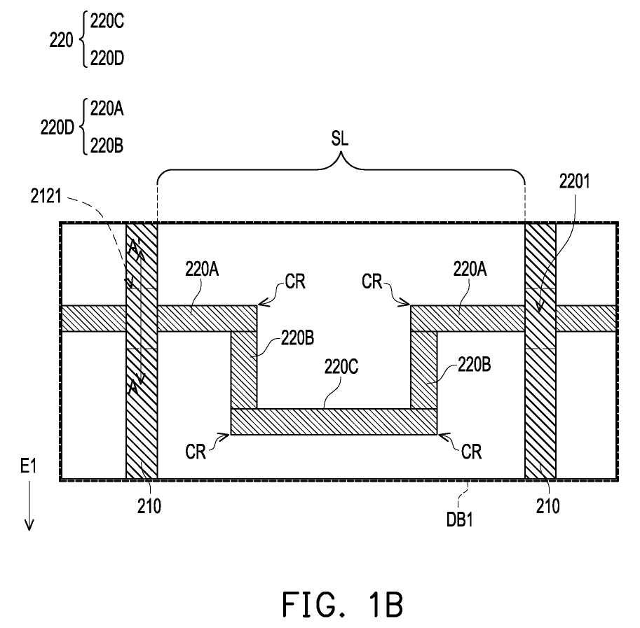

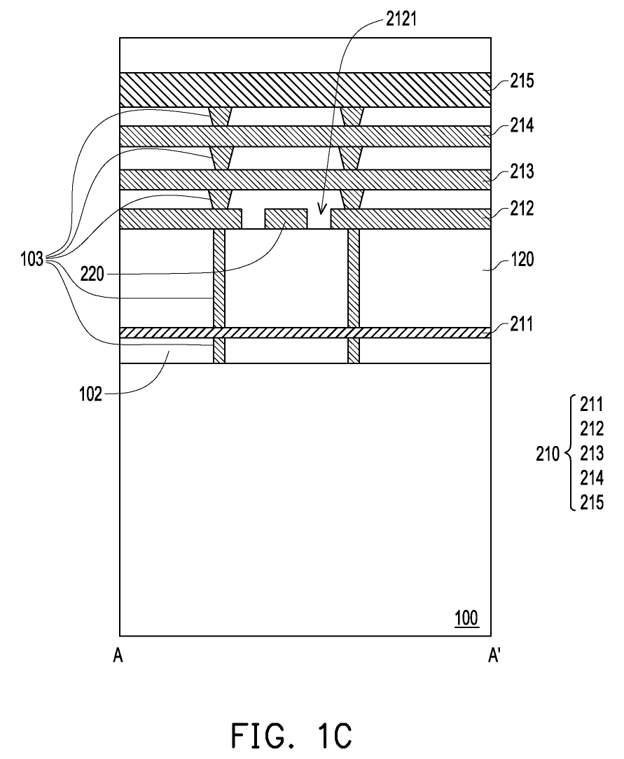

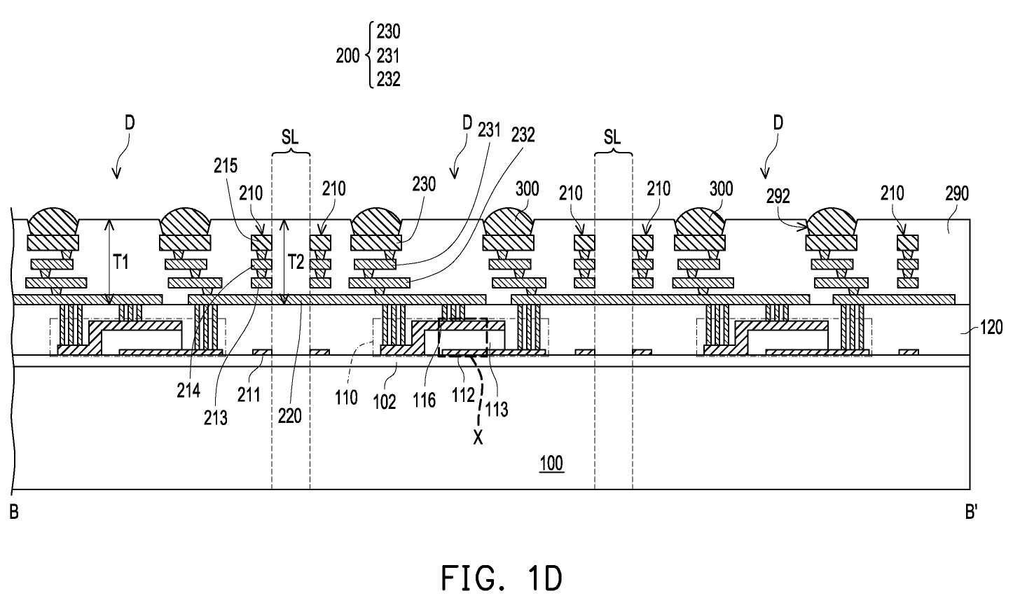

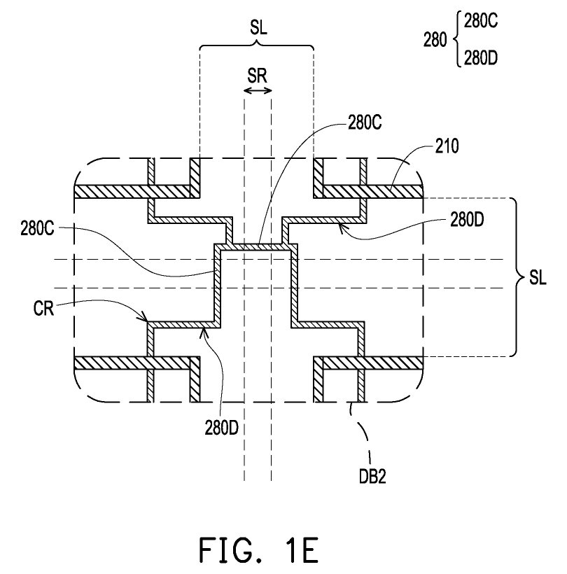

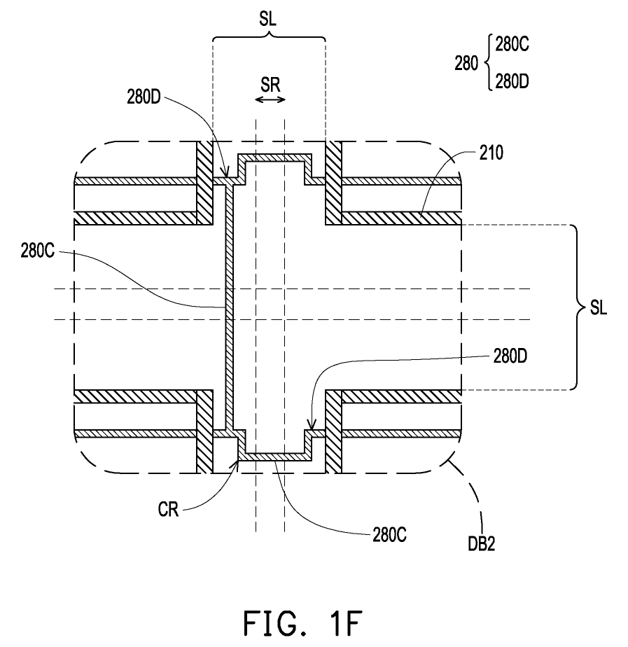

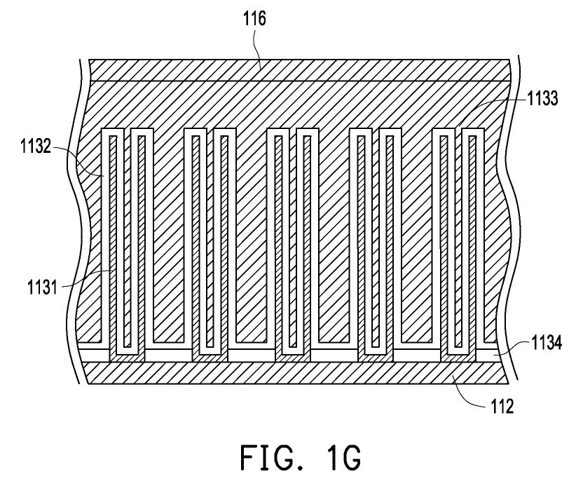

Referring to FIGS. 1A to 1D, a semiconductor device of this embodiment is a wafer 10. The wafer 10 may include multiple semiconductor dies D and die-to-die interconnects 220. The semiconductor dies D are located on both sides of a predetermined scribe-line area SL. The die-to-die interconnects 220 electrically connect adjacent semiconductor dies D. Each semiconductor die D may include an array component 110, an interconnect structure 200, a sealing structure 210, and a connection terminal 300 formed on a substrate 100 of the wafer 10. The substrate 100 may include a semiconductor substrate, a glass substrate, or a ceramic substrate, such as a silicon substrate, a silicon-germanium substrate, silicon carbide, an aluminum nitride substrate, a sapphire substrate, or a combination thereof. In addition, the substrate 100 may include silicon on insulator, but the disclosure is not limited thereto.

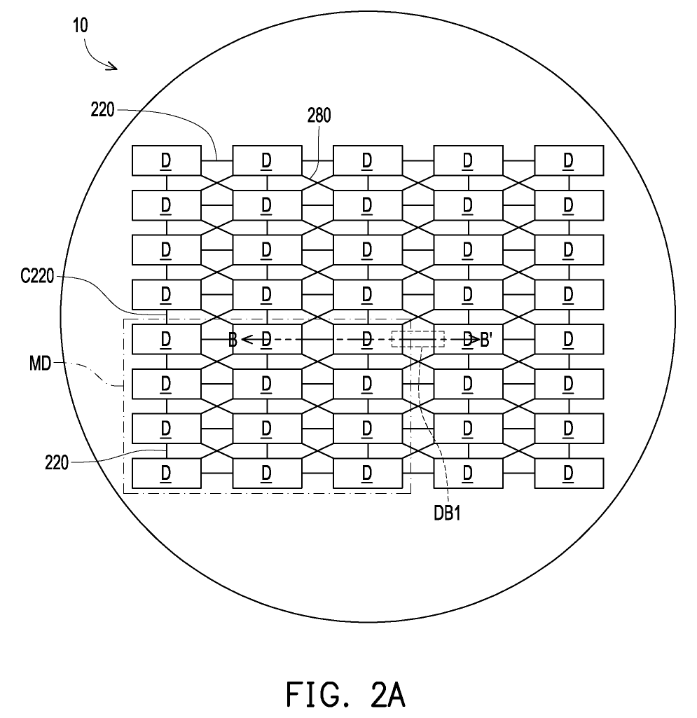

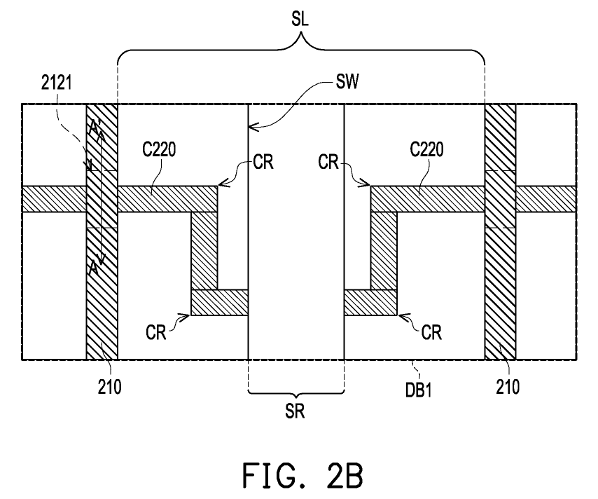

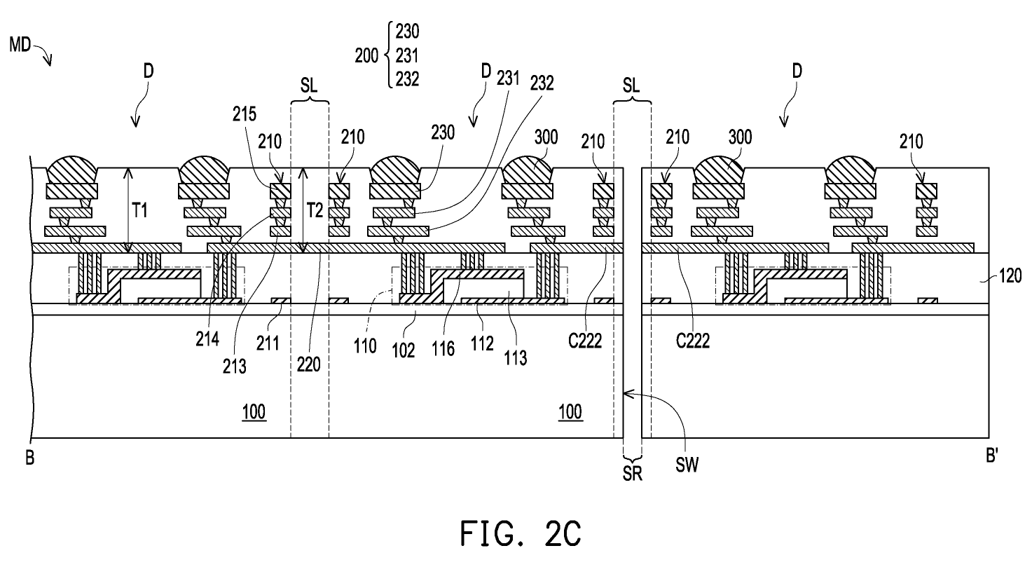

It should be noted that, for the purpose of simplifying the diagram, the die-to-die interconnects 220 are represented by straight lines in FIG. 1A to indicate the electrical connection relationship with adjacent semiconductor dies D. However, the die-to-die interconnects 220 of the disclosure are not straight lines. As shown in FIG. 1B, which represents a partial enlarged view of a dashed box DB1 in FIG. 1A, the die-to-die interconnects 220 of the disclosure include multiple crack-prevention corners CR in the top view, thus cracks generated during the dicing process can be prevented from extending along the die-to-die interconnects 220 into the semiconductor dies D, thereby improving the yield of the semiconductor device. In addition, subsequent FIGS. 2A, 6A, and 7A are also drawn based on the same simplification reason as mentioned above, and it should be understood that the die-to-die interconnects 220 of the disclosure are not straight lines, but include the multiple crack-prevention corners CR.

The array component 110 includes multiple identical or similar components, for example, a silicon capacitor array including multiple silicon capacitors or a memory cell array including multiple memory cells. The disclosure does not limit the type of the array component 110. In some embodiments, a buffer layer 102 may be included between the array component 110 and the substrate 100. A cover layer 120 may be disposed on the array component 110.

In this embodiment, the array component 110 may be a silicon capacitor array, and the silicon capacitor array of one semiconductor die D may be connected in series with the silicon capacitor array of another semiconductor die D through the die-to-die interconnects 220. In this way, the breakdown voltage of the device may be increased. In another embodiment, the silicon capacitor array of one semiconductor die D may be connected in parallel with the silicon capacitor array of another semiconductor die D through the die-to-die interconnects 220. In this way, the total capacitance value of the semiconductor device may be increased. As shown in FIG. 1D, the array component 110 may include a first planar electrode 112, a capacitor component 113, and a second planar electrode 116. The capacitor component 113 is located between the first planar electrode 112 and the second planar electrode 116. It should be noted that, as mentioned earlier, since a line B-B' in FIG. 1A is used to indicate the electrical connection relationship with adjacent semiconductor dies D at locations corresponding to the die-to-die interconnects 220, the line B-B' at the locations corresponding to the die-to-die interconnects 220 should be understood as a cross-section based on the extension direction of the die-to-die interconnects 220, and FIG. 1D presents the die-to-die interconnects 220 extending from one semiconductor die D to another semiconductor die D. Furthermore, for the same reason, subsequent FIGS. 2C, 6C, and 7B should also be understood as cross-sections based on the extension direction of the die-to-die interconnects 220 at the locations corresponding to the die-to-die interconnects 220.

FIG. 1G corresponds to the position of a dashed box X in FIG. 1D. In this embodiment, as shown in FIG. 1G, the capacitor component 113 may include a bottom electrode 1131, a dielectric layer 1132, and a top electrode 1133. The dielectric layer 1132 may be disposed on the bottom electrode 1131. The capacitor component 113 may further include a stop layer 1134 disposed on the first planar electrode 112, and the bottom of the bottom electrode 1131 may pass through the stop layer 1134 to contact the first planar electrode 112. It should be noted that the capacitor component 113 in FIG. 1G is merely one example, and the capacitor component 113 of the disclosure may be fabricated according to various known processes and structures, not limited to the content drawn in this embodiment. In addition, any known structure and process may be used to fabricate the array component 110 of the disclosure, not limited to silicon capacitor arrays.

In this embodiment, the die-to-die interconnect 220 may be disposed on the cover layer 120, and the interconnect structure 200 may be disposed above the die-to-die interconnect 220. The die-to-die interconnect 220 and the interconnect structure 200 may be located in the interlayer dielectric layer 290 on the cover layer 120. In other words, the die-to-die interconnect 220 may be disposed above the array component 110. The interconnect structure 200 may include conductive layers 231, 232 disposed in a stacking manner and a pad layer 230, and the conductive layers 231, 232 and the pad layer 230 may be electrically connected through conductive vias. In this embodiment, the conductive layer 231 is located between the conductive layer 232 and the pad layer 230. In some embodiments, the conductive layers 231, 232 may include tungsten, aluminum, copper, alloys of the above metals, or other suitable conductive materials. The interconnect structure 200 may be electrically connected to the array component 110 through the die-to-die interconnect 220, for example, electrically connected to the first electrode 112 and the second electrode 116 of the array component 110. In this way, interconnection between multiple semiconductor dies D may be achieved through the die-to-die interconnects 220, thereby improving the performance of the semiconductor device (for example, increasing capacity or improving electrical performance).

The pad layer 230 is located at the top of the interconnect structure 200. In some embodiments, the pad layer 230 may include tungsten, aluminum, copper, alloys of the above metals, or other suitable conductive materials. In some embodiments, the pad layer 230 and the conductive layers 231, 232 located beneath may include the same or different conductive materials.

The interlayer dielectric layer 290 includes multiple openings 292, and the openings 292 respectively expose pad layers 230. Connection terminals 300 may be disposed above the pad layers 230. In this embodiment, the connection terminals 300 may fill the openings 292 and contact the pad layers 230, thereby electrically connecting with the pad layers 230. In some embodiments, an under-bump metallization (UBM) layer may further be included between the connection terminal 300 and the pad layer 230, but the disclosure is not limited thereto. In some embodiments, the connection terminals 300 may include micro bumps, controlled collapse chip connection (C4) bumps, Ball Grid Array (BGA), or other types of connection terminals.

In some embodiments, the die-to-die interconnects 220 connect the semiconductor dies D arranged along an X direction, or connect the semiconductor dies D arranged along a Y direction.

As shown in FIG. 1C, the sealing structure 210 is located at the edge of each semiconductor die D to surround the array component 110, thereby protecting the array component 110. For example, the sealing structure 210 may serve as a protective barrier to enhance the mechanical strength of the semiconductor die D, preventing the semiconductor die D from being damaged by external forces during manufacturing or subsequent packaging and dicing processes. Furthermore, the sealing structure 210 helps prevent moisture and other external contaminants from penetrating the array component 110, avoiding any impact on the array component 110.

Referring to FIGS. 1B, 1C, and 1D, the sealing structure 210 may include a first sealing ring 211, an open ring 212, a second sealing ring 213, a third sealing ring 214, and a fourth sealing ring 215 disposed in a stacking manner, but the disclosure is not limited thereto. In this embodiment, the die-to-die interconnect 220 passes through an opening 2121 of the open ring 212 to electrically connect to the array component 110. From another perspective, the die-to-die interconnect 220 has a portion 2201 that overlaps with the vertical projection of the second sealing ring 213, the third sealing ring 214, and/or the fourth sealing ring 215, and does not overlap with the open ring 212.

The first sealing ring 211 may be located on the substrate 100. In some embodiments, the first sealing ring 211 may be formed in the cover layer 120, and may belong to the same conductive layer as the first electrode 112 or the second electrode 116 of the array component 110. For example, the first sealing ring 211 and the first electrode 112 (or the second electrode 116) may be formed simultaneously through metal layer deposition and patterning processes. In some embodiments, the first sealing ring 211 may be electrically coupled to the underlying substrate 100 through a conductive via 103, but the disclosure is not limited thereto.

The open ring 212 may be located above the first sealing ring 211. In this embodiment, the open ring 212 may include a conductive layer, and may be electrically connected to the first sealing ring 211 through the conductive via 103. In some embodiments, the die-to-die interconnect 220 may be formed in the same conductive layer as the open ring 212. For example, the die-to-die interconnect 220 and the open ring 212 may be formed simultaneously through metal layer deposition and patterning processes, during which the die-to-die interconnect 220 is delineated from the open ring 212.

The second sealing ring 213 may be located above the open ring 212, and may span across the die-to-die interconnect 220. In this embodiment, the second sealing ring 213 may be located in the interlayer dielectric layer 290. The second sealing ring 213 may include a conductive layer, and may be electrically connected to the open ring 212 through the conductive via 103. In some embodiments, the second sealing ring 213 may be formed in the same conductive layer as the conductive layer 232 of the interconnect structure 200. For example, the second sealing ring 213 and the conductive layer 232 may be formed simultaneously through metal layer deposition and patterning processes.

The third sealing ring 214 may be located above the second sealing ring 213, and may span across the die-to-die interconnect 220. The third sealing ring 214 is electrically connected to the second sealing ring 213 through the conductive via. In this embodiment, the third sealing ring 214 may be located in the interlayer dielectric layer 290. The third sealing ring 214 may include a conductive layer, and may be electrically connected to the second sealing ring 213 through the conductive via 103. In some embodiments, the third sealing ring 214 may formed in the same conductive layer as the conductive layer 231 of the interconnect structure 200. For example, the third sealing ring 214 and the conductive layer 231 may be formed simultaneously through metal layer deposition and patterning processes.

The fourth sealing ring 215 may be located above the third sealing ring 214, and may span across the die-to-die interconnect 220. In this embodiment, the fourth sealing ring 215 may be located in the interlayer dielectric layer 290. The fourth sealing ring 215 may include a conductive layer, and may be electrically connected to the third sealing ring 214 through the conductive via 103. In some embodiments, the fourth sealing ring 215 may be formed in the same conductive layer as the pad layer 230 of the interconnect structure 200. For example, the fourth sealing ring 215 and the pad layer 230 may be formed simultaneously through metal layer deposition and patterning processes.

In this embodiment, the predetermined scribe-line area SL is located between the sealing structures 210 of adjacent semiconductor dies D. In some embodiments, a thickness T2 of the interlayer dielectric layer 290 within the predetermined scribe-line area SL may be less than or equal to a thickness T1 of the interlayer dielectric layer 290 located at an inner side of the sealing structure 210. As a result, the top surface of the predetermined scribe-line area SL is recessed relative to the top surface of the semiconductor die D (not shown in the drawing). Furthermore, in this embodiment, by arranging the die-to-die interconnects 220 in the relatively lower metal layers (i.e., metal layers disposed between the array component 110 and the interconnect structure 200), the influence of the die-to-die interconnects 220 on the surface flatness of the predetermined scribe-line area SL may be reduced. Accordingly, an additional planarization process on the predetermined scribe-line area SL is not required.

The die-to-die interconnect 220 includes multiple crack-prevention corners CR between the sealing structures 210 of two adjacent semiconductor dies D. In other words, the crack-prevention corners CR are located in the predetermined scribe-line area SL. Specifically, in this embodiment, the die-to-die interconnect 220 may include a predetermined scribe-line portion 220C and crack-prevention portions 220D located on both sides of the predetermined scribe-line portion 220C. The extension direction of the predetermined scribe-line portion 220C differs from the extension direction of the predetermined scribe-line area SL in which the predetermined scribe-line portion 220C is located, and the crack-prevention corners CR are located in the crack-prevention portions 220D. In FIG. 1B, the predetermined scribe-line area SL extends along a first direction E1 (also known as the dicing direction), and the crack-prevention portions 220D of the die-to-die interconnect 210 include multiple first segments 220B parallel to the first direction E1 and multiple second segments 220A perpendicular to the first direction E1. The crack-prevention corner CR is located at the intersection between the first segment 220B and the second segment 220A. In other words, the second segment 220A may be connected to the first segment 220B via the crack-prevention corner CR. In this embodiment, the crack-prevention corners CR may include right-angle corners. As shown in FIG. 1B, the extension direction of the predetermined scribe-line portion 220C may be perpendicular to the first direction E1. In this embodiment, the extension direction of the second segment 220A (i.e., the portion of the die-to-die interconnect 220 that passes through the opening 2121 of the open ring 212) is the same as the extension direction of the predetermined scribe-line portion 220C.

Furthermore, in some embodiments, the wafer 10 may have die-to-die interconnects 280 for connecting adjacent semiconductor dies D arranged along a diagonal direction.

As shown in FIG. 1E, which represents a partial enlarged view of a dashed box DB2 in FIG. 1A, the die-to-die interconnects 280 of this embodiment include multiple crack-prevention corners CR in the top view. In detail, the die-to-die interconnect 280 may include a predetermined scribe-line portion 280C and crack-prevention portions 280D located on both sides of the predetermined scribe-line portion 280C. The extension direction of the predetermined scribe-line portion 280C differs from the extension direction of the predetermined scribe-line area SL in which the predetermined scribe-line portion 280C is located, and the crack-prevention corners CR are located in the crack-prevention portions 280D. FIGS. 1F and 1E share the same inventive concept, with the difference lying in the number of the crack-prevention corners CR, which results in variations in their shapes. Moreover, the die-to-die interconnect 280 and the die-to-die interconnect 220 are based on the same inventive concept; therefore, the related technical description will not be repeated herein. The predetermined scribe-line portion 280C corresponds to the portion that overlaps with the scribe line SR during the dicing process.

In some other embodiments of the disclosure, a semiconductor device MD may be fabricated by performing a dicing process on the wafer 10. For example, the wafer 10 may be cut along a dashed box shown in FIG. 2A to obtain the semiconductor device MD. The dicing process may be performed using a saw blade or other suitable methods. The semiconductor device MD includes multiple semiconductor dies D, and the quantity of the semiconductor dies D in a single semiconductor device MD may be determined according to requirements. In this embodiment, the array component 110 may be a memory cell array including multiple memory cell components. Each semiconductor die D may have any capacity size, for example but not limited to, 2GB. According to the disclosure, the capacity of the semiconductor device MD may be flexibly adjusted by changing the dicing range. For example, when a higher capacity is required, then the semiconductor device MD is made to include more semiconductor dies D.

Through this method, it is not necessary to change the design of the semiconductor die D to meet different capacity requirements, thereby reducing the design cost of the semiconductor device MD. Furthermore, in the present disclosure, the die-to-die interconnect 220 is used to electrically interconnect one semiconductor die D to another semiconductor die D, thereby integrating multiple semiconductor dies D into a single semiconductor device MD, rather than combining multiple semiconductor dies D through a packaging process. Compared with conventional planar (side-by-side) packaging techniques, the wafer-level planar integration enabled by the die-to-die interconnects 220 eliminates the need for package-level spacing, substrate routing, and associated keep-out zones, thereby significantly reducing the overall area consumption of the semiconductor device MD (also referred to as a chip).

Referring to FIGS. 2B and 2C, during the dicing process, the wafer 10 may be cut along the scribe line SR within the predetermined scribe-line area SL, thereby leaving a cut trace SW at the edge of the semiconductor device MD. In this embodiment, the portion of the die-to-die interconnect 220 located in the predetermined scribe-line area SL at the edge of the semiconductor device MD is cut during the dicing process, resulting in cut die-to-die interconnects C220. In other words, the semiconductor die D located at the edge of the semiconductor device MD includes the cut die-to-die interconnect C220. The cut die-to-die interconnect C220 passes through the opening 2121 of the open ring 212 (refer to FIG. 1C) of the sealing structure 210 and extends to the edge (that is, the cut trace SW) of the semiconductor device MD.

Additionally, the central region of the semiconductor device MD may include multiple predetermined scribe-line areas SL that are not cut during the dicing process, and these uncut predetermined scribe-line areas SL contain uncut die-to-die interconnects 220, as shown in FIG. 1B.

In this embodiment, the crack-prevention corners CR inhibit cracks generated during the dicing process from propagating along the die-to-die interconnects 220 into the semiconductor dies D, thereby preventing damage to the array component 110 located at the inner side of the sealing structure 210. In this embodiment, both the uncut die-to-die interconnect 220 (see FIG. 1B) and the cut die-to-die interconnect C220 (see FIG. 2B) include the crack-prevention corners CR. Furthermore, in this embodiment, components that are the same as or similar to components shown in FIGS. 1A to 1F will be represented by the same reference numerals, and the same or similar components will not be repeated here.

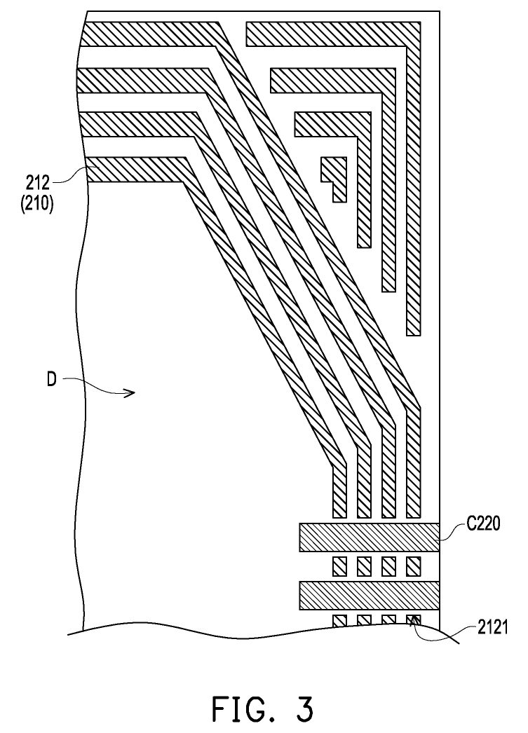

In the foregoing embodiments, each semiconductor die D includes one sealing structure 210, but the disclosure is not limited thereto. The quantity of the sealing structures 210 may be adjusted according to requirements. As shown in FIG. 3, a single semiconductor die D may include multiple sealing structures 210. The sealing structures 210 are arranged between the array component 110 and the edge of each semiconductor die D, such that one sealing structure 210 surrounds another sealing structure 210.

When a single semiconductor die D includes multiple sealing structures 210, the die-to-die interconnects coupled between semiconductor dies D pass through the multiple sealing structures 210. As shown in FIG. 3, the cut die-to-die interconnects C220 pass through the openings 2121 of the open rings 212 of multiple sealing structures 210. It should be noted that, although not illustrated, it may be understood that uncut die-to-die interconnects also pass through the openings 2121 of the open rings 212 of the multiple sealing structures 210. Moreover, the cut die-to-die interconnects C220 in FIG. 3 are merely used to illustrate the relative positional relationship with the sealing structures 210, and the complete structure of the cut die-to-die interconnects C220 is not shown.

In the foregoing embodiments, each die-to-die interconnect 220 (refer to FIG. 1B) has four crack-prevention corners CR located in the predetermined scribe-line area SL. However, the disclosure does not limit the quantity of the crack-prevention corners CR. Preferably, each die-to-die interconnect 220 may include two or more crack-prevention corners CR located in the predetermined scribe-line area SL. For example, the quantity of the crack-prevention corners CR may be a multiple of 2. The following examples are based on other variations of the disclosure.

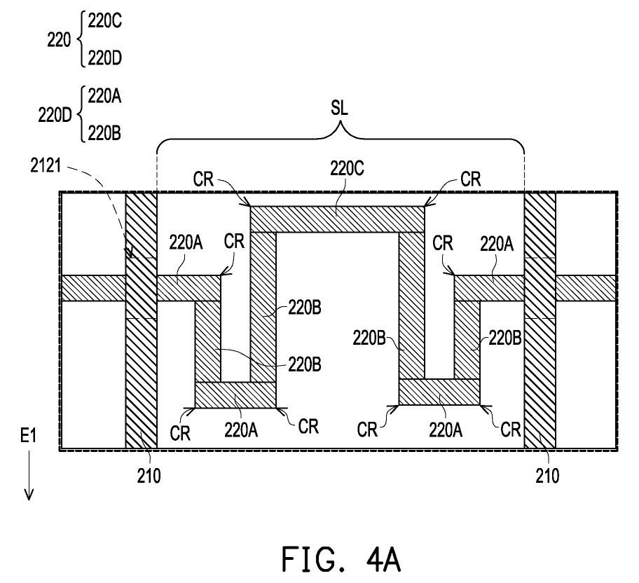

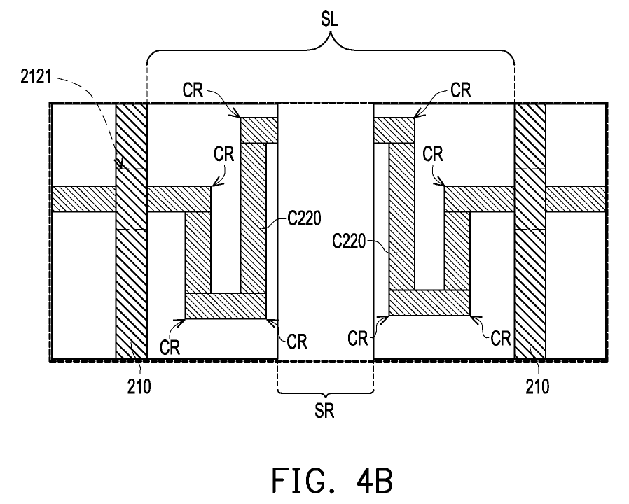

Referring to FIGS. 4A and 4B, in this embodiment, the die-to-die interconnect 220 may include eight crack-prevention corners CR. Furthermore, the cut die-to-die interconnect C220 may include four crack-prevention corners CR. In addition, in this embodiment, components that are the same as or similar to components in the foregoing embodiments will be represented by the same reference numerals, and the same or similar components will not be repeated here.

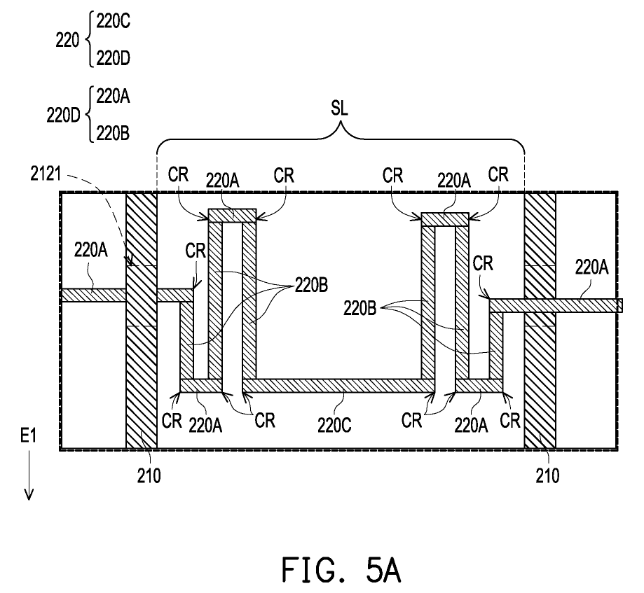

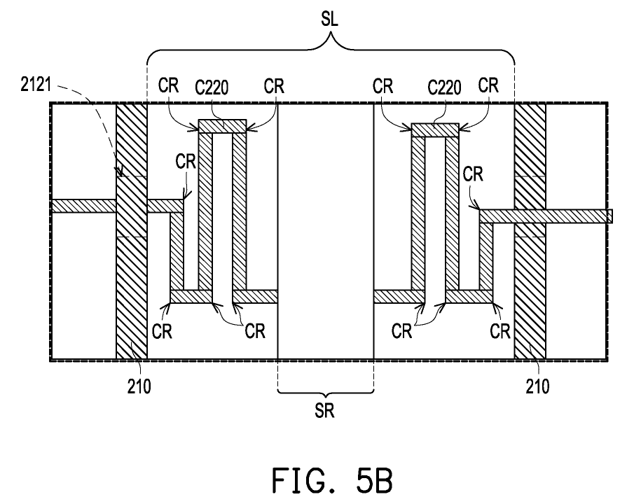

Referring to FIGS. 5A and 5B, in this embodiment, the die-to-die interconnect 220 includes twelve crack-prevention corners CR. Furthermore, the cut die-to-die interconnect C220 includes six crack-prevention corners CR. In addition, in this embodiment, components that are the same as or similar to components in the foregoing embodiments will be represented by the same reference numerals, and the same or similar components will not be repeated here.

In the above-mentioned embodiment, the connection terminals 300 (refer to FIG. 2C) of the semiconductor die D are electrically connected to the pad layer 230. However, the disclosure is not limited thereto. The following examples are based on other variations of the disclosure.

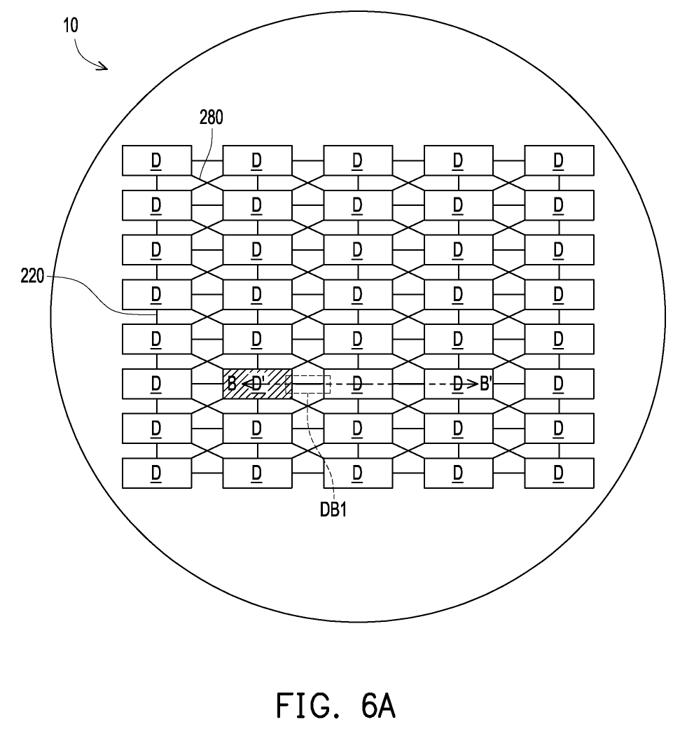

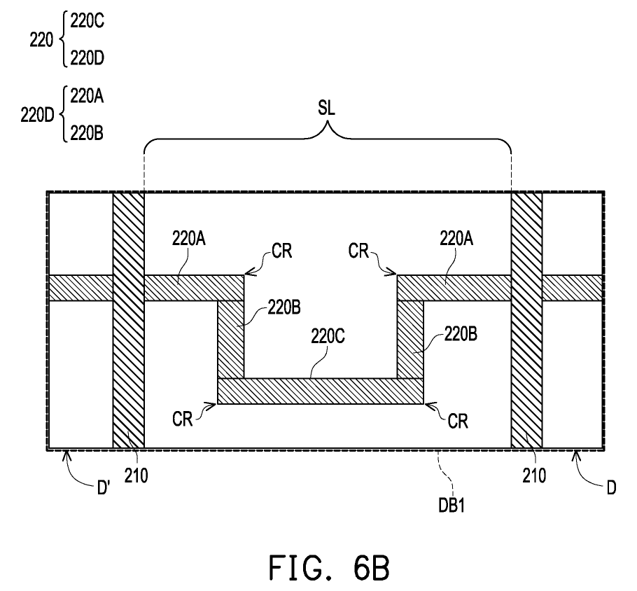

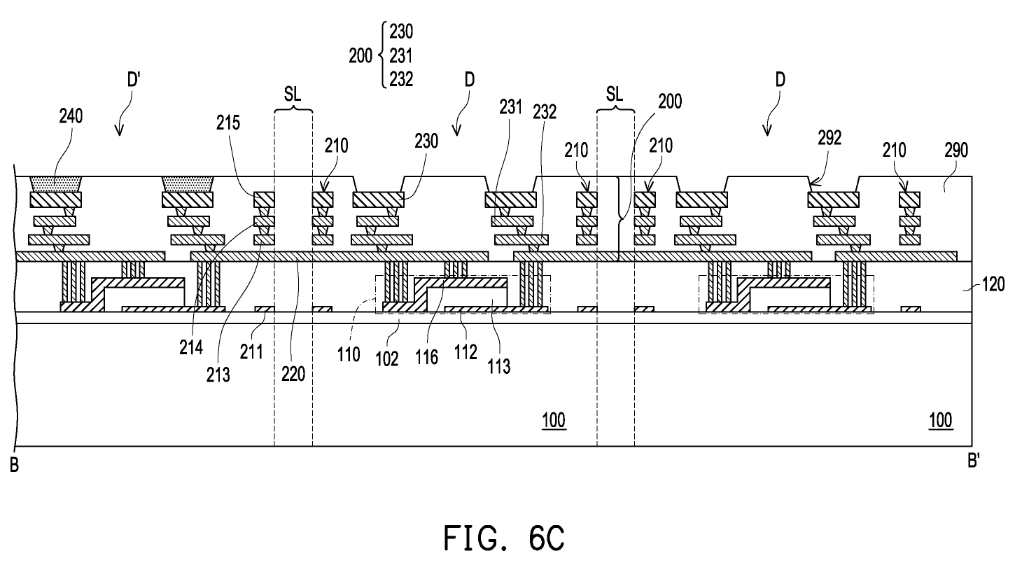

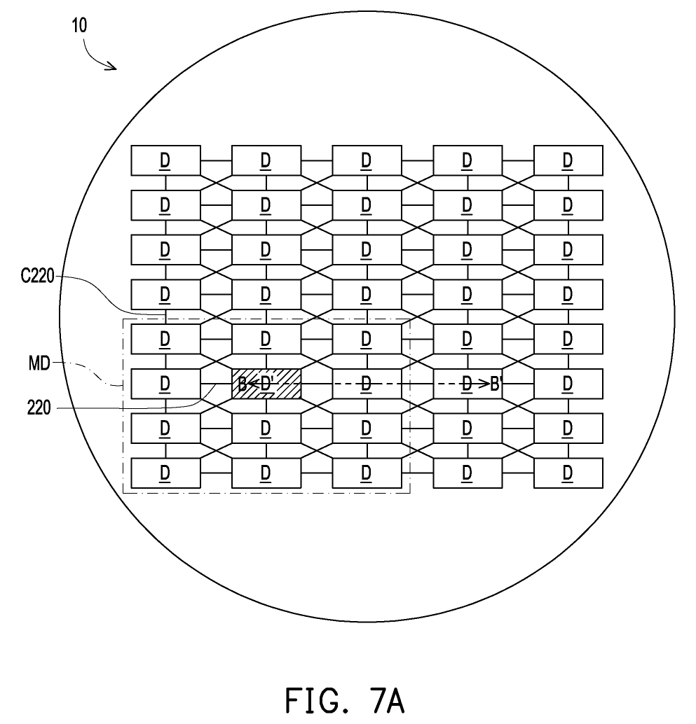

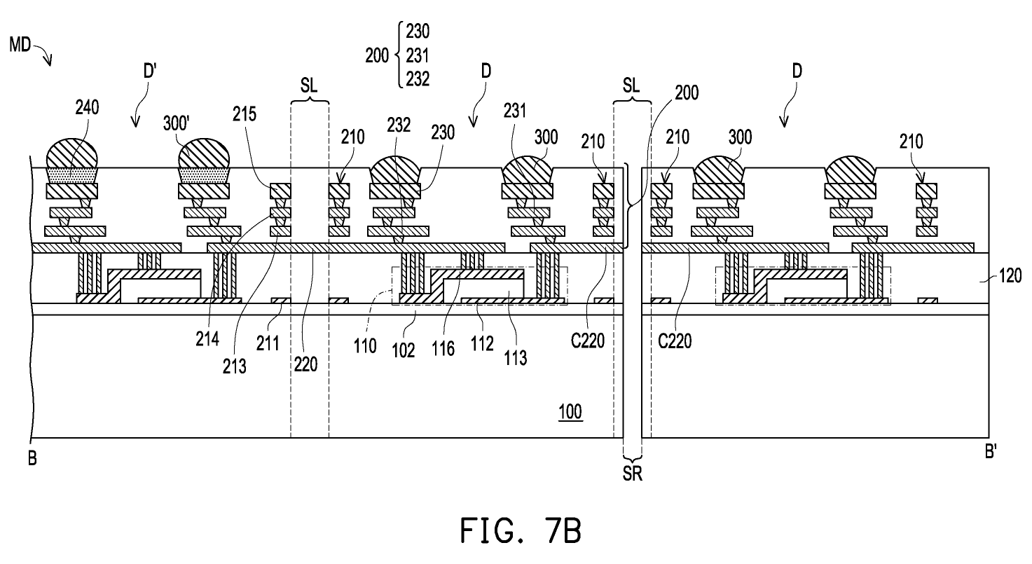

Referring to FIGS. 6A and 6B, in this embodiment, before forming the connection terminals 300 (shown in FIG. 7B), each semiconductor die in the wafer 10 may be tested. After testing, semiconductor dies with no detected abnormalities may be designated as first semiconductor dies D, and semiconductor dies in which abnormalities are detected (such as open circuit, short circuit, or leakage issues) may be designated as second semiconductor dies D'. The second semiconductor dies D' have the same structure as the first semiconductor dies D, and the only difference therebetween is that the second semiconductor dies D' may have electrical or functional abnormalities due to process deviations, contamination, or other factors. Here, the detailed structure of the second semiconductor dies D' will not be repeated.

In this embodiment, after testing, the position of the second semiconductor die D' on the wafer 10 may be known. Then, a barrier structure 240 may be formed on the pad layer 230 of the interconnect structure 200 of the second semiconductor die D' using 3D printing technology, photolithography technology, or other suitable methods. For example, the barrier structure 240 may be filled into the opening 292 of the interlayer dielectric layer 290 of the second semiconductor die D', allowing the barrier structure 240 to contact the pad layer 230.

Next, as shown in FIGS. 7A and 7B, the connection terminal 300 is disposed above each pad layer 230. The connection terminal 300 of the first semiconductor die D is electrically connected to the pad layer 230, while the connection terminal 300 of the second semiconductor dies D' is electrically isolated from the pad layer 230 due to the barrier structure 240 disposed between the pad layer 230 and the connection terminal 300. In this embodiment, due to the presence of the barrier structure 240, the top surfaces of the connection terminals 300 of the first semiconductor dies D are lower than the top surfaces of the connection terminals 300' of the second semiconductor dies D'.

After forming the connection terminals 300, the wafer 10 may be subjected to a dicing process to obtain the semiconductor device MD. In this embodiment, the semiconductor device MD may include the first semiconductor die D and the second semiconductor die D'. In the known manufacturing process of stitched chips, if any semiconductor die is determined to be abnormal during the testing stage, then the entire stitched chip would be scrapped. Alternatively, a complex dicing process would be required to remove specific abnormal semiconductor dies. As a result, resources are wasted. In contrast, in this embodiment, by disposing the barrier structure 240, not only the interference from the second semiconductor die D' is reduced, but also the presence of abnormal semiconductor dies (that is, the second semiconductor die D') in the semiconductor device MD is allowed. As a result, this embodiment does not require a complex dicing process to specifically remove the second semiconductor die D' from the semiconductor device MD, thereby improving process yield and reducing resource consumption, thus lowering manufacturing costs.

According to the semiconductor device of the disclosure, in the actual production process, regardless of how many semiconductor dies are required to be disposed in an integrated circuit to meet performance requirements, the same wafers may still be uniformly produced, for example, wafers including 1000 semiconductor dies. Then, based on the required performance, semiconductor devices with four semiconductor dies, semiconductor devices with two semiconductor dies, or semiconductor devices with only one semiconductor die may be diced during the dicing process. Through this method, the same mask may be used to fabricate integrated circuits with different performances, and the frequency of updating photolithography equipment can also be reduced, which not only shortens the development time, but also lowers production costs. Furthermore, the crack-prevention corners of the die-to-die interconnect according to the disclosure can prevent cracks generated during the dicing process from extending along the die-to-die interconnect into the semiconductor dies, thereby improving the product yield. Therefore, the semiconductor device of the disclosure belongs to a type of green semiconductor technology.

The disclosed wafer‑level integration architecture is well suited for emerging applications in which performance scalability, form‑factor efficiency, and cost reduction are critical design considerations. By enabling multiple semiconductor dies to be flexibly combined at the wafer level without redesigning die layouts, the disclosed structure allows manufacturers to derive products of different capacities or performance grades from a single mask set, thereby shortening development cycles and reducing production costs.

In addition, the crack‑prevention configuration improves dicing robustness, allowing larger stitched dies or higher‑density integrated circuits to be fabricated with enhanced yield. This benefit makes the disclosed technology particularly advantageous for markets that demand high‑capacity memory, power‑efficient computing, and dense analog or passive arrays—such as mobile devices, consumer electronics, automotive electronics, and edge‑processing systems—where reliability and compact area usage are increasingly important.

What is claimed is:

1. A semiconductor device, comprising:
a plurality of semiconductor dies located on both sides of a predetermined scribe-line area; and
a die-to-die interconnect electrically connecting the semiconductor dies, wherein in a top view, the die-to-die interconnect comprises a plurality of crack-prevention corners located in the predetermined scribe-line area.

2. The semiconductor device as claimed in claim 1, wherein the die-to-die interconnect comprises a predetermined scribe-line portion and crack-prevention portions located on both sides of the predetermined scribe-line portion, an extension direction of the predetermined scribe-line portion is different from an extension direction of the predetermined scribe-line area, and the crack-prevention corners are located in the crack-prevention portions.

3. The semiconductor device as claimed in claim 2, wherein the predetermined scribe-line area extends along a first direction, and the crack-prevention portions of the die-to-die interconnect comprises:
a plurality of first segments, wherein each of the first segments extends parallel to the first direction; and
a plurality of second segments, wherein each of the second segments extends perpendicular to the first direction, and is connected to one of the first segments via one of the crack-prevention corners.

4. The semiconductor device as claimed in claim 3, wherein the extension direction of the predetermined scribe-line portion is perpendicular to the first direction.

5. The semiconductor device as claimed in claim 1, wherein a quantity of the crack-prevention corners is greater than or equal to 2.

6. The semiconductor device as claimed in claim 1, wherein a quantity of the crack-prevention corners is a multiple of 2.

7. The semiconductor device as claimed in claim 1, wherein the crack-prevention corners comprise right-angle corners.

8. The semiconductor device as claimed in claim 1, wherein each of the semiconductor dies comprises:
an array component; and
a sealing structure located at an edge of each of the semiconductor dies to surround the array component, wherein the sealing structure comprises a first sealing ring and an open ring disposed in a stacking manner, and the die-to-die interconnect passes through an opening of the open ring to electrically connect to the array component.

9. The semiconductor device as claimed in claim 8, wherein the array component is a silicon capacitor array, and the silicon capacitor array of one of the semiconductor dies is connected in series with the silicon capacitor array of another one of the semiconductor dies through the die-to-die interconnect.

10. The semiconductor device as claimed in claim 8, wherein the array component is a silicon capacitor array, and the silicon capacitor array of one of the semiconductor dies is connected in parallel with the silicon capacitor array of another one of the semiconductor dies through the die-to-die interconnect.

11. The semiconductor device as claimed in claim 8, wherein the die-to-die interconnect is disposed above the array component, and each of the semiconductor dies further comprises:
an interconnect structure disposed above the die-to-die interconnect, and electrically connected to the array component via the die-to-die interconnect, wherein the interconnect structure comprises a conductive layer and a pad layer disposed in a stacking manner; and
a connection terminal disposed above the pad layer,
wherein the semiconductor dies comprise a first semiconductor die and a second semiconductor die, and the connection terminal of the first semiconductor die is electrically connected to the pad layer.

12. The semiconductor device as claimed in claim 11, wherein the second semiconductor die further comprises:
a barrier structure disposed between the pad layer and the connection terminal, such that the connection terminal of the second semiconductor die is electrically isolated from the pad layer.

13. The semiconductor device as claimed in claim 8, wherein the sealing structure further comprises a second sealing ring, the open ring is disposed above the first sealing ring, and the second sealing ring is disposed above the open ring and spans across the die-to-die interconnect.

14. The semiconductor device as claimed in claim 8, wherein the die-to-die interconnect of one of the semiconductor dies located at an edge of the semiconductor device passes through the open ring and extends to the edge of the semiconductor device.

15. The semiconductor device as claimed in claim 8, wherein each of the semiconductor dies comprises a plurality of the sealing structures, and the sealing structures are arranged between the array component and the edge of each of the semiconductor dies, such that one of the sealing structures surrounds another one of the sealing structures.

16. The semiconductor device as claimed in claim 8, wherein an extension direction of a portion of the die-to-die interconnect passing through the opening of the open ring is same as an extension direction of the predetermined scribe-line portion.

17. The semiconductor device as claimed in claim 1, further comprising a plurality of the die-to-die interconnects, wherein one of the die-to-die interconnects connects the semiconductor dies arranged along an X direction, another one of the die-to-die interconnects connects the semiconductor dies arranged along a Y direction, and still another one of the die-to-die interconnects connects the semiconductor dies arranged along a diagonal direction.
